(19) United States
(12) Patent Application Publication
(10) Pub. No.: US 2025/0174923 A1
(43) Pub. Date: May 29, 2025

(54) ELECTRICAL CONNECTOR FOR MONITORING CAMERA AND ASSOCIATED MONITORING CAMERA

(71) Applicant: Faurecia Clarion Electronics Europe, Paris (FR)

(72) Inventor: Sébastien BARBARAT, Paris (FR)

(21) Appl. No.: 18/964,101

(22) Filed: Nov. 29, 2024

(30) Foreign Application Priority Data
Nov. 29, 2023 (FR) FR 2313242

(51) Int. Cl. H01R 12/73; H01R 12/55; H01R 27/02

(52) U.S. Cl. CPC H01R 12/73; H01R 12/55; H01R 27/02; H01R 2201/26

(57) ABSTRACT

An electrical connector for a monitoring camera that includes: a main body and first and second connecting elements, the main body having a front surface, each of the first and second connecting elements forming an axial projection with respect to the front surface. The first connecting element has a support and at least one terminal. The at least one terminal has a connecting member, elastically deformable by axial pressure. The electrical connector is configured so that the first and second connecting elements are suitable for connection to a first and a second separate electrical device.

### TECHNICAL FIELD

The present invention relates to an electrical connector for a monitoring camera, of the type comprising: a main body and first and second connecting elements, the main body extending along a main axis and comprising a front surface substantially perpendicular to said main axis, each of the first and second connecting elements forming an axial projection with respect to said front surface, the first connecting element comprising: a support, projecting from the front surface of the body to an end surface; and at least one terminal joined to said end surface; the at least one terminal comprising a connecting member, elastically deformable by pressure along the main axis.

### SUMMARY

The invention is particularly applicable to monitoring cameras for motor vehicles. Such a camera is described in document U.S. Pat. No. 9,628,680.

Such cameras are, for example, mounted in the passenger compartment of a motor vehicle, to be incorporated into a system for monitoring the driver and/or occupant(s) of said vehicle. The layout of the various components of such a camera must take into account the limited space available.

A purpose of the present invention is to provide an improved arrangement of monitoring cameras for motor vehicles. To this end, the subject of the invention is directed to an electrical connector of the aforementioned type, configured so that the first and second connecting elements are suitable for connection to a first and a second separate electrical device.

According to other advantageous aspects of the invention, the electrical connector comprises one or more of the following features, taken individually or in all technically possible combinations:
the connecting member of the at least one terminal comprises a first lug extending from the end surface of the support to a free end, said first lug comprising a contact portion further from said end surface than said free end;
the at least one terminal further comprises: a second lug, secured to the first lug; and a spring arranged between the second lug and the support, said spring being compressed so as to exert a force on the first lug opposed to said support;
the electrical connector further comprises at least a first and a second electrical cable, attached to the main body and connected to the first and second connecting elements, respectively.

The invention further relates to a monitoring camera comprising: an optical lens; a light-emitting diode; first and second printed circuit boards, attached to the light-emitting diode and the optical lens, respectively; first and second electrical devices, arranged on the first and second printed circuit boards, respectively, and connected to the light-emitting diode and the optical lens, respectively; and an electrical connector as described above, such that the first and second connecting elements are connected simultaneously to the first and second electrical devices.

According to other advantageous aspects of the invention, the monitoring camera comprises one or more of the following features, taken individually or in all technically possible combinations:
the first electrical device comprises at least one connection area pressed against the at least one terminal so as to elastically deform the connecting member of said at least one terminal and ensure electrical contact between said at least one terminal and said first electrical device;
the first and second printed circuits are arranged substantially parallel to one another and separated by a non-zero distance;
one edge of the second printed circuit board has a U-shaped cutout and the support for the first connecting element of the connector is arranged in said cutout.

The invention further relates to a vehicle equipped with a monitoring camera as described above.

### BRIEF DESCRIPTION OF THE DRAWINGS

The invention will become clearer on reading the following description, given solely by way of non-limiting example, and made with reference to the drawings, wherein:

FIG. 1 is a detailed view of an electrical connector according to one embodiment of the invention;

FIG. 2 is a detailed view of the electrical connector of FIG. 1;

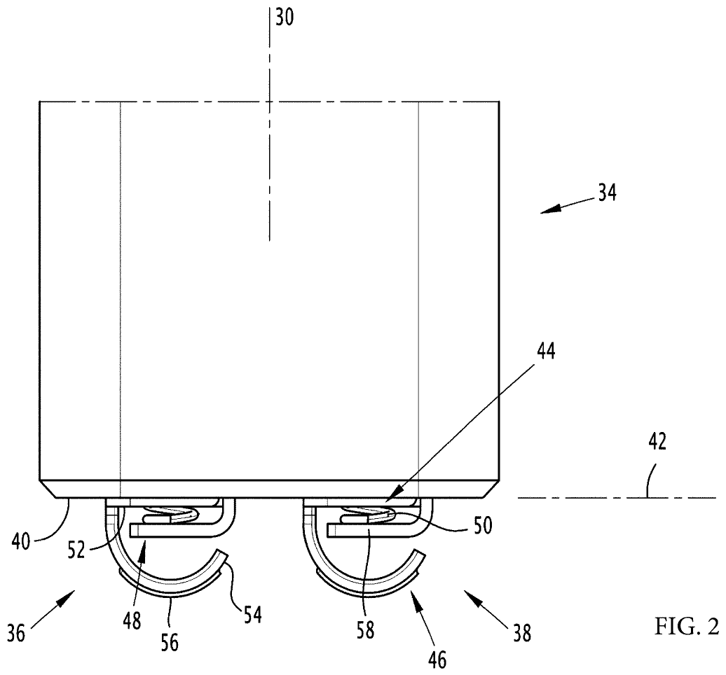

FIG. 3 is a detailed view of a monitoring camera according to one embodiment of the invention, with the electrical connector of FIGS. 1 and 2; and

FIG. 4 is a detailed view of elements of the monitoring camera of FIG. 3.

### DETAILED DESCRIPTION

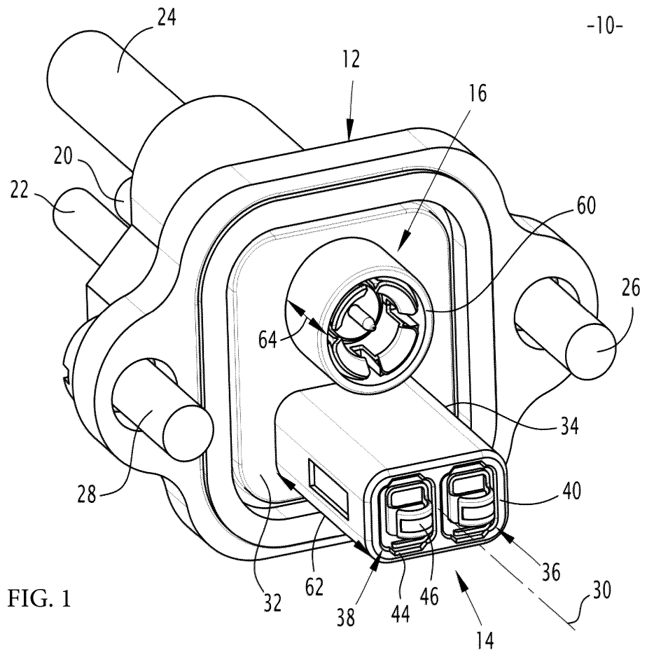

FIG. 1 shows an electrical connector 10 according to one embodiment of the invention.

The electrical connector 10 comprises: a main body 12; and first 14 and second 16 connecting elements.

In the embodiment shown, the electrical connector 10 further comprises at least a first 20, 22 and a second 24 electrical cable; and at least one mechanical fastening element 26, 28.

The main body 12 extends along a main axis 30, between opposing first and second ends. The first end is materialized by a front surface 32, substantially perpendicular to the main axis 30.

The main body 12 is made of an electrically insulating material such as one or more plastic materials

Each of the first 14 and second 16 connecting elements projects axially from the front surface 32 of the main body 12.

The first connecting element 14 comprises a support 34 and at least one first terminal 36. In the embodiment shown, the first connecting element 14 further comprises a second terminal 38.

The support 34 extends from the front surface 32 of the main body 12, parallel to the main axis 30, to an end surface 40. Preferably, said end surface 40 is substantially perpendicular to the main axis 30.

In the embodiment shown, the end surface 40 has an elongated shape, extending along a secondary axis 42 substantially perpendicular to the main axis 30; and each of the first 36 and second 38 terminals is disposed at said end surface 40, said first 36 and second 38 terminals being aligned along the secondary axis 42.

In the embodiment shown, the first 36 and second 38 terminals are substantially identical and will be described together hereinafter as “the terminal.”

The terminal 36, 38 comprises an annular body 44 and a first lug 46. In the embodiment shown, the terminal 36, 38 further comprises a second lug 48 and a spring 50. The second lug 48 is formed in one piece with the annular body 44 and the first lug 46.

The annular body 44 comprises a closed blade arranged around an axis parallel to the main axis 30. The annular body 44 is assembled to the support 34, so that at least one edge 52 of said annular body 44 is flush with the end surface 40 of said support or projects slightly from said end surface 40.

The first lug 46 protrudes axially from the annular body 44. More specifically, the first lug 46 extends from the edge 52 of the annular body 44, to a first free end 54.

The first lug 46 is hook-shaped between said edge 52 and said first free end 54. More specifically, the first lug 46 comprises a contact portion 56, located between said edge 52 and said first free end 54. Along the main axis 30, the contact portion 56 is further away from the end surface 40 of the support 34 than the first free end 54 of the first lug 46.

The second lug 48 extends from the edge 52 of the annular body 44 to a second free end. The second lug 48 is arranged axially between the end surface 40 of the support 34 and the first lug 46.

The second lug 48 comprises a bearing portion 58, extending substantially parallel to the end surface 40 of the support 34.

The spring 50 is a compression spring. More specifically, the spring 50 extends and compresses parallel to the main axis 30, between a first end (not shown), received inside the support 34, and a second end bearing on the bearing portion 58 of the second lug 48. The spring 50 is in a semi-compressed state, so as to exert, on the second lug 48, an axial force opposite the front surface 32 of the main body 12. The axial force is transmitted to the first lug 46 via the annular body 44.

Preferably, the terminal 36, 38 is assembled to the support 34 with axial play, so that the spring 50 is able to push the first 46 and second 48 lugs away from the front surface 32.

The second connecting element 16 extends from the front surface 32 of the main body 12, parallel to the main axis 30, to an end edge 60.

As will be described below, the first 14 and second 16 connecting elements are configured to be connected to separate electrical devices.

In the embodiment shown, a first distance 62 between the end surface 40 of the support 34 and the front surface 32 is greater than a second distance 64 between the end edge 60 of the second connecting element 16 and said front surface 32.

The first 20, 22 and second 24 electrical cables are attached to the main body 12 and electrically connected to the first 14 and second 16 connecting elements, respectively. Preferably, the first 20, 22 and second 24 electrical cables are attached to the second end of the main body 12, opposite the front surface 32.

In the embodiment shown, the connector 10 comprises two first electrical cables 20, 22 connected to the first 36 and second 38 terminals, respectively, of the first connecting element 14.

The at least one mechanical fastening element 26, 28 is designed to secure the connector 10 to an electrical device or to an electrical assembly. In the embodiment shown, the connector 10 has two mechanical fastening elements 26, 28, in the form of two screws inserted into holes in the main body 12.

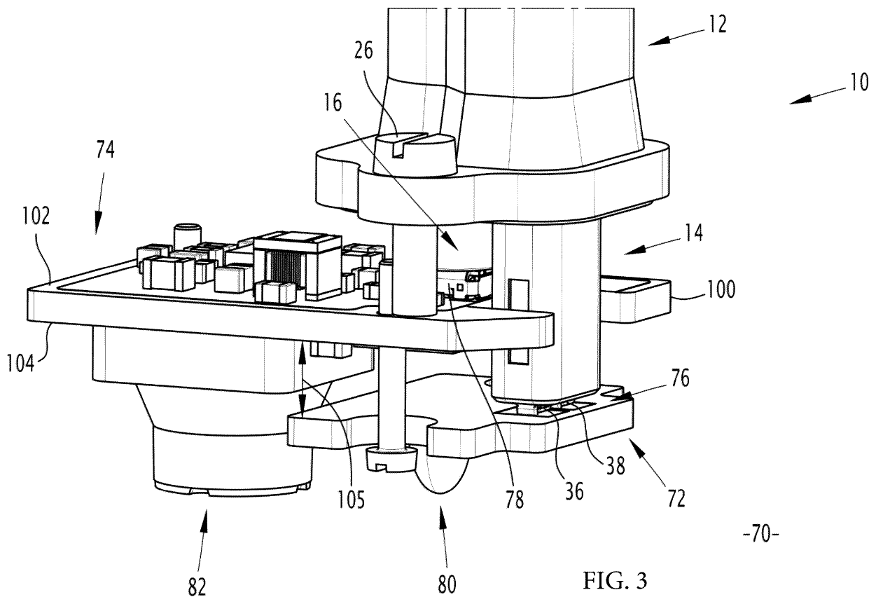

FIG. 3 shows a monitoring camera 70 according to one embodiment of the invention. The camera 70 is designed, for example, to be attached in the passenger compartment of a motor vehicle (not shown).

The camera 70 comprises a connector 10 as described above

The camera 70 further comprises: a first 72 and a second 74 printed circuit board; a first 76 and a second 78 electrical device; a light-emitting diode 80; and an optical lens 82.

The camera 70 further comprises a casing (not shown) enclosing at least the first 72 and second 74 printed circuit boards.

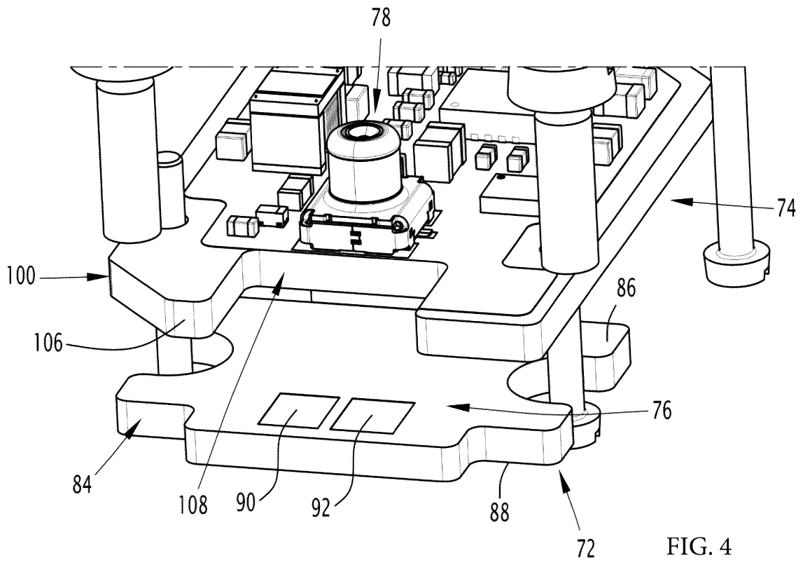

The first 72 and second 74 printed circuit boards are partially shown in FIG. 4.

The first printed circuit board 72 comprises a first substantially flat substrate 84, said first substrate comprising first 86 and second 88 faces, opposite one another and substantially flat.

The first electrical device 76 is disposed on the second face 86 of the first substrate 84. The light-emitting diode 80 is attached to the second face 88 of said first substrate

In the embodiment shown, the first printed circuit board 72 further comprises a first electrical connection (not shown) between the first electrical device 76 and the light-emitting diode 80

The first electrical device 76 is adapted to be electrically connected to the first connecting element 14 of the connector 10.

In the embodiment shown, the first electrical device 76 comprises a first 90 and a second 92 connection area, intended to be electrically connected to the first 36 and second 38 terminals of the first connecting element 14, respectively.

Preferably, each of the first 90 and second 92 connection areas is formed by a metal layer or metal foil. In a first embodiment, said metal layer is deposited on the first face 86 of the first substrate 84. In a second embodiment, a surface of said first face 86 is formed of an insulating layer, said metal layer is disposed beneath said insulating layer and a slot is provided in said insulating layer to strip said metal layer so as to form each of the first 90 and second 92 connection areas.

The second printed circuit board 74 comprises a substantially flat second substrate 100, said second substrate comprising first 102 and a second 104 faces, opposite one another and substantially flat.

The second electrical device 78 is disposed on the second face 102 of the second substrate 100. The optical lens 82 is attached to the second face 104 of said second substrate.

In the embodiment shown, the second printed circuit board 74 further comprises a second electrical connection (not shown) between the second electrical device 78 and the optical lens 82.

The second electrical device 78 is adapted to be electrically connected to the second connecting element 16 of the connector 10. In the embodiment shown, said second connecting element 16 and said second electrical device 78 can be joined by translation perpendicular to the first face 102 of the second substrate 100

In the embodiment shown, the first 72 and second 74 printed circuit boards of the camera 70 are attached to the casing (not shown) of said camera so that the first 84 and second 100 substrates are arranged substantially parallel to one another. The first face 86 of the first substrate 84 and the second face 104 of the second substrate 100 face one another. The first 84 and second 100 substrates are spaced apart by a non-zero third distance 105, perpendicular to said substrates

Furthermore, in the embodiment shown, an edge 106 of the second substrate 100, opposite the first substrate 84, has a U-shaped cutout 108.

In an operating configuration of the camera 70, shown in FIG. 3, the first 14 and second 16 connecting elements of the connector 10 are simultaneously connected to the first 76 and second 78 electrical devices.

More specifically, in the operating configuration of the camera 70, the contact portion 56 of the first lug 46 of each of the first 36 and second 38 terminals of the first connecting element 14 is pressed against the first 90 and second 92 connection area of the first electrical device 76, respectively. The first lug 46 is slightly elastically deformed, so as to generate a pressure force between each contact portion 56 and the corresponding connection area 90, 92.

Electrical contact is thus established between each terminal 36, 38 and the corresponding connection area 90, 92. The spring effect exerted by the first lugs 46 maintains said electrical contact in the event of shocks or vibrations to which the camera 70 is subjected, particularly when said camera is fitted to a motor vehicle

Preferably, the pressure exerted by the spring 50 further enhances the maintenance of electrical contact in the event of shocks or vibrations to the camera 70.

Furthermore, in the operating configuration of the camera 70, the second connecting element 16 of the connector 10 is connected to the second electrical device 78. The first 62 and second 64 connector distances and the third distance 105 between the first 84 and second 100 substrates are configured to enable such simultaneous connection of the first 14 and second 16 connecting elements with the first 76 and second 78 electrical devices.

In the embodiment shown, in the operating configuration of the camera 70, the support 34 of the first connecting element 14 of the connector 10 is received in the cutout 108 of the second substrate 100. This configuration makes the connector more ergonomic.

Preferably, in the operating configuration of the camera 70, the at least one mechanical fastening element 26, 28 mechanically fastens the main body 12 of the connector 10 to the casing (not shown) of the camera.

The connector 10 described above combines a small footprint with an efficient electrical connection, owing to the spring effect exerted by the terminals 36, 38 of the first connecting element 14 of said connector on the connection areas 90, 92 of the first electronic device 76.

The combination of this connector with two superimposed printed circuit boards 72, 74 makes it possible to create a space-saving camera 70 that is easy to integrate into a vehicle passenger compartment.

1. An electrical connector, comprising a main body and first and second connecting elements, the main body extending along a main axis and comprising a front surface substantially perpendicular to said main axis, each of the first and second connecting elements forming an axial projection with respect to said front surface,
the first connecting element comprising: a support, projecting from the front surface of the body to an end surface; and at least one terminal joined to said end surface;
the at least one terminal comprising a connecting member, elastically deformable by pressure along the main axis; and
the electrical connector being configured so that the first and second connecting elements are suitable for connection to a first and a second separate electrical device.

2. The electrical connector according to claim 1, wherein the connecting member of the at least one terminal comprises a first lug extending from the end surface of the support to a free end, said first lug comprising a contact portion further from said end surface than said free end.

3. The electrical connector according to claim 2, wherein the at least one terminal further comprises: a second lug, secured to the first lug; and a spring arranged between the second lug and the support, said spring being compressed so as to exert a force on the first lug opposed to said support.

4. The electrical connector according to claim 1, further comprising at least a first and a second electrical cable, attached to the main body and connected to the first and second connecting elements, respectively.

5. A monitoring camera comprising: an optical lens; a light-emitting diode; first and second printed circuit boards, attached to the light-emitting diode and the optical lens, respectively; first and second electrical devices, arranged on the first and second printed circuit boards, respectively, and connected to the light-emitting diode and the optical lens, respectively; and an electrical connector according to claim 1, such that the first and second connecting elements are connected simultaneously to the first and second electrical devices.

6. The monitoring camera according to claim 5, wherein first electrical device comprises at least one connection area pressed against the at least one terminal so as to elastically deform the connecting member of said at least one terminal and ensure electrical contact between said at least one terminal and said first electrical device.

7. The monitoring camera according to claim 6, wherein the first and second printed circuit boards are arranged substantially parallel to one another and separated by a non-zero distance.

8. The monitoring camera according to claim 7, wherein: one edge of the second printed circuit board has a U-shaped cutout; and the support for the first connecting element of the connector is arranged in said cutout.

9. A vehicle equipped with a monitoring camera according to claim 5.
